(19) United States
(12) Patent Application Publication
(10) Pub. No.: US 2021/0295153 A1
(43) Pub. Date: Sep. 23, 2021

(54) LEARNING DEVICE

(71) Applicant: KIOXIA CORPORATION, Tokyo (JP)

(72) Inventors: Ryota YOSHIZAWA, Yokohama Kanagawa (JP); Kenichiro FURUTA, Shinjuku Tokyo (JP); Yuma YOSHINAGA, Yokohama Kanagawa (JP); Osamu TORII, Minato Tokyo (JP); Tomoya KODAMA, Kawasaki Kanagawa (JP)

(21) Appl. No.: 17/184,026

(22) Filed: Feb. 24, 2021

(30) Foreign Application Priority Data
Mar. 17, 2020 (JP) 2020-046492

(51) Int. Cl. G06N 3/08; G06N 3/04; H03M 13/45

(52) U.S. Cl. CPC G06N 3/08; H03M 13/45; G06N 3/04

(57) ABSTRACT

A learning device includes an encoding unit, a plurality of permutation units, a plurality of decoding units, a selection unit, and a learning unit. The encoding unit is configured generate an encoded word by encoding a transmission word. The permutation units are configured to permutate the encoded word according to different permutation manners to generate a plurality of permutated encoded words. The decoding units are configured to perform message passing decoding on the plurality of permutated encoded words, to generate a plurality of decoded words. The message passing decoding involves weighting of values of a word transmitted during the message passing decoding. The selection unit is configured to select one or more of the decoded words. The learning unit is configured to perform learning of weighting values of the weighting based on the transmission word and the selected one or more of the decoded words.

### CROSS-REFERENCE TO RELATED APPLICATION

This application is based upon and claims the benefit of priority from Japanese Patent Application No. 2020-046492, filed Mar. 17, 2020, the entire contents of which are incorporated herein by reference.

### FIELD

Embodiments described herein relate generally to a learning device.

### BACKGROUND

As one of decoding methods of an error correction code, belief-propagation (BP) on a Tanner graph is known. BP on the Tanner graph can be equivalently expressed by a neural network. A technique such as weighted-BP has been proposed in which the neural network is used to further improve performance of belief-propagation by learning a weight to be applied to a message propagated through belief-propagation.

### BRIEF DESCRIPTION OF THE DRAWINGS

FIG. 1 illustrates an example of a Tanner graph used in Weighted-BP.

FIG. 2 illustrates an example in which message propagation on a Tanner graph is expressed by a neural network.

FIG. 3 is a block diagram illustrating an example of a configuration of a learning device according to an embodiment.

FIG. 4 is a flowchart illustrating an example of a learning process in an embodiment.

FIG. 5 is a flowchart illustrating an example of an inference process in an embodiment.

FIG. 6 illustrates a hardware configuration example of the learning device according to an embodiment.

### DETAILED DESCRIPTION

Embodiments provide a learning device which can improve error correction (decoding) capability of a decoding method using a learned weight.

In general, according to an embodiment, a learning device includes an encoding unit, a plurality of permutation units, a plurality of decoding units, a selection unit, and a learning unit. The encoding unit is configured generate an encoded word by encoding a transmission word. The permutation units are configured to permutate the encoded word according to different permutation manners to generate a plurality of permutated encoded words. The decoding units are configured to perform message passing decoding on the plurality of permutated encoded words, respectively, to generate a plurality of decoded words. The message passing decoding involves weighting of values of a word transmitted during the message passing decoding. The selection unit is configured to select one or more of the decoded words. The learning unit is configured to perform learning of weighting values of the weighting based on the transmission word and the selected one or more of the decoded words.

Hereinafter, a learning device according to one or more example embodiments will be described with reference to the accompanying drawings. The present disclosure is not limited to the example embodiment described below.

A configuration example of a learning device which learns the weights in a Weighted-BP technique will be described. The applicable decoding methods are not limited to Weighted-BP, and may be another message passing decoding technique in which a weight is added to a message to be transmitted. An example of learning the weight of a neural network representing a decoding process will be described. A model other than the neural network may be used, and the weight may be learned using a learning method applicable to such other model. The weight being learned may be referred to as a weighting value.

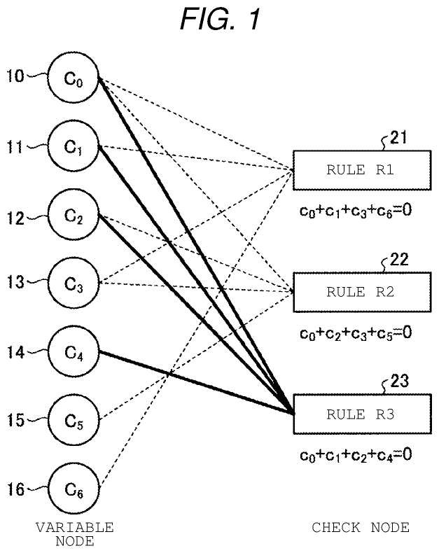

First, a brief configuration of a Weighted-BP method will be described. FIG. 1 illustrates an example of a Tanner graph used for the Weighted-BP. The applicable graphs are not limited to a Tanner graph, and the other bipartite graphs such as a factor graph may be used. The Tanner graph may be interpreted as a graph expressing a rule structure which a code word serving as a decoding target has to satisfy. FIG. 1 illustrates an example of the Tanner graph for a 7-bit Hamming code (an example of a code word).

Variable nodes 10 to 16 correspond to 7-bit sign bits C₀ to C₆. Check nodes 21 to 23 correspond to three rules R1, R2, and R3. A sign bit is not limited to 7 bits. The number of rules is not limited to three. In FIG. 1, a rule is used in which a value becomes 0 when all connected sign bits are added. For example, the rule R3 represents a rule in which an addition value of the sign bits C₀, C₁, C₂, and C₄ corresponding to the variable nodes 10, 11, 12, and 14 connected to the corresponding check node 23 becomes 0.

In BP, soft-decision decoding using the Tanner graph is performed. The soft-decision decoding is a decoding method for inputting information indicating a probability that each sign bit is 0. For example, a log-likelihood ratio (LLR) in which a ratio between likelihood that the sign bit is 0 and likelihood that the sign bit is 1 is expressed as a logarithm can be used as an input of the soft-decision decoding.

In the soft-decision decoding on the Tanner graph, each variable node exchanges the LLR with other variable nodes via the check node. It is finally determined whether the sign bit of each variable node is 0 or 1. The LLR exchanged in this way is an example of messages transmitted using BP (example of the message passing decoding).

For example, the soft-decision decoding on the Tanner graph is performed according to the following procedure.

(S1) The variable node transmits the input LLR (channel LLR) to the connected check node.

(S2) The check node determines the LLR (external LLR) of the variable node of a transmission source, based on the LLR of the other connected variable nodes and the corresponding rule, and return the LLR to each variable node (transmission source).

(S3) The variable node updates the LLR of an own node, based on the external LLR returned from the check node and the channel LLR, and transmits the updated LLR to the check node.

The variable node determines whether the sign bit corresponding to the own node is 0 or 1, based on the LLR obtained after (S2) and (S3) are repeated.

In this method, the message (LLR) based on the LLR transmitted by a certain variable node may return to the variable node via the check node. For this reason, decoding performance may be degraded in some cases.

The Weighted-BP is a method for minimizing degradation of the decoding performance. According to the Weighted-BP, influence of a returning message can be attenuated by adding the weight to the message on the Tanner graph.

It is difficult to theoretically obtain a value of an optimum weight for each message. Therefore, according to the Weighted-BP, the optimum weight is obtained by converting message propagation on the Tanner graph into the neural network and expressing and learning the neural network.

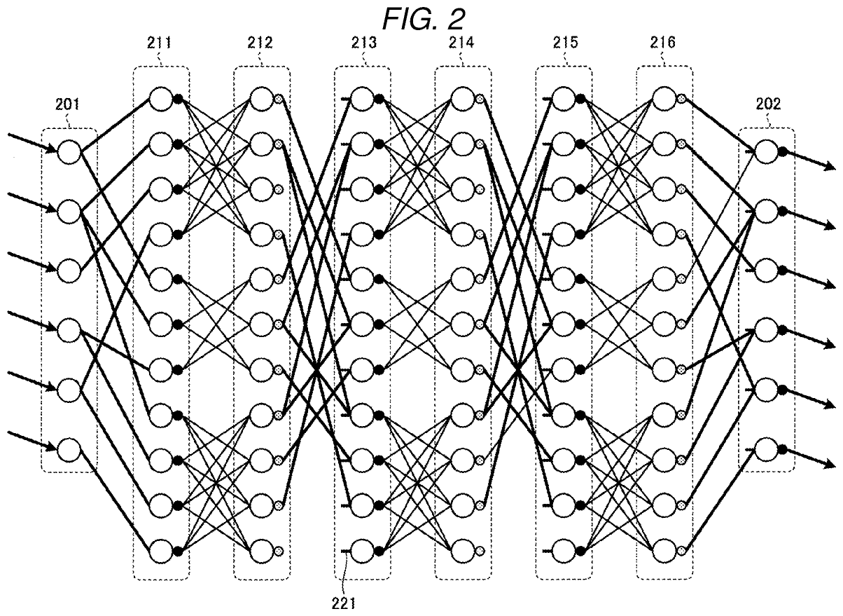

FIG. 2 illustrates an example in which a message propagation on a Tanner graph is expressed by a neural network. FIG. 2 illustrates an example of the neural network that expresses the message propagation when the BP is repeatedly performed 3 times for a certain code in which 6 sign bits and 11 edges are provided on the Tanner graph.

The neural network includes an input layer 201, odd layers 211, 213, and 215, which are odd-numbered intermediate layers, even layers 212, 214, and 216, which are even-numbered intermediate layers, and an output layer 202. The input layer 201 and the output layer 202 correspond to the variable nodes of the Tanner graph. The odd layers 211, 213, and 215 correspond to the messages propagating from a certain variable node on the Tanner graph to the check node. The even layers 212, 214, and 216 correspond to the messages propagating from a certain check node on the Tanner graph to the variable node. According to the BP method, when the message propagating from a certain variable node (referred to as a variable node A) to a certain check node (referred to as a check node B) is calculated, calculation is performed using the message excluding the message propagated from the check node B out of all of the messages propagated to the variable node A, and the message obtained by performing the calculation is transmitted to the check node B. For example, a transition from the input layer 201 to the odd layer 211 corresponds to the calculation performed using the variable node in this way. For example, this calculation corresponds to an activation function in the neural network.

According to the Weighted-BP method, the weight to be assigned to the transition between the nodes of the neural network is learned. In the example illustrated in FIG. 2, the weights assigned to the transitions between the nodes (input layer 201 and odd layer 211, even layer 212 and odd layer 213, even layer 214 and odd layer 215, even layer 216 and output layer 202) indicated by thick lines are learned.

For example, the calculations in the odd layer, the even layer, and the output layer of the neural network are respectively expressed by Equations (1), (2), and (3) below.

$$\begin{matrix}{x}_{i , e = ( v , c )} = tanh ( \frac{1}{2} ( {w}_{i , v} {l}_{v} + {\sum }_{{e}^{′} = ( v , {c}^{′} ) , {c}^{′} \neq c} {w}_{i , e , {e}^{′}} {x}_{i - 1 , {e}^{′}} ) ) & ( 1 ) \\ {x}_{i , e = ( v , c )} = 2 {tanh}^{- 1} ( {\sum }_{{e}^{′} = ( {v}^{′} , c ) , {v}^{′} \neq v} {x}_{i - 1 , {e}^{′}} ) & ( 2 ) \\ {o}_{v} = σ ( {w}_{2 L + 1 , v} {l}_{v} + {\sum }_{{e}^{′} = ( v , {c}^{′} )} {w}_{2 L + 1 , v , {e}^{′}} {x}_{2 L , {e}^{′}} ) & ( 3 )\end{matrix}$$

Here, i is a numerical value representing an order of the intermediate layer, and for example, has a value of 1 to 2L (where L is a value obtained by dividing a total number of the intermediate layers by 2, and corresponds to the number of repeated BP decoding). Here, e=(v, c) is a value for identifying a transition (edge) that connects a variable node v and a check node c. Here, x_{i, e=(v, c)} represents an output to the nodes (variable node ᵥ or check node _{c}) to which an edge identified by e=(v, c) is connected in the i^{-th} intermediate layer. Here, oᵥ represents an output to each node in the output layer.

In a case of i=1, that is, in a case of a first odd layer (odd layer 211 in the example of FIG. 2), the check node is not connected thereto in advance. Accordingly, xᵢ₋₁, e′ corresponding to the output from the previous layer cannot be obtained. In this case, for example, Equation (1) may be used under a condition of x_{i-1, e′}+x_{0, e′}=0. In this case, the calculation using Equation (1) is equivalent to the calculation using an equation in which a second term on the right side of Equation (1) does not exist.

Here, lᵥ represents an input LLR (channel LLR). Here, lᵥ is used for the odd layer other than the first odd layer 211. In FIG. 2, for example, a short thick line such as a line 221 represents that the channel LLR is input.

Here, w_{i, v} represents a weight assigned to lᵥ in the i^{-th} intermediate layer. Here, w_{1, e,′} represents a weight assigned to an output (x_{i-1, e′}) from the previous layer via an edge e′ other than an edge e serving as a process target in the i^{-th} intermediate layer. Here, w_{2L+1, v} represents a weight assigned to lᵥ in the output layer. Here, w_{2L+1, v, e′} represents a weight assigned to an output (x_{2L, e′}) from the previous layer via the edge e′ other than the edge e serving as the process target in the output layer.

For example, σ is a sigmoid function represented by σ(x)=(1+e^{-x})⁻¹.

According to the Weighted-BP, the weights included in Equations (1) and (3) above are learned. A learning method of the weight may be any desired method, and for example, a back propagation method (gradient descent method) is applicable.

The neural network illustrated in FIG. 2 is an example of a feedforward neural network in which data flows in one direction. A recurrent neural network (RNN) including a recurrent structure may be used. In a case of the recurrent neural network, it is possible to standardize the weights to be learned.

For example, in the learning, learning data including the LLR corresponding to a code word in which noise has been added to the code word and a code word corresponding to the correct answer data is used. That is, the LLR is input to the neural network, and the weight is learned so that an output (corresponding to a decoding result) output from the neural network is closer to the correct answer data.

Such weighted-BP is generally applicable to a block error correction code including a low-density parity-check (LDPC) code. For example, it is possible to adopt an encoding method using a Bose-Chandhuri-Hocquenghem (BCH) code or an encoding method using a Reed Solomon (RS) code.

For example, when the BCH code is employed, there is a possibility that a large number of small cycles may be generated. The small cycle represents that a message (LLR) based on the LLR transmitted by a certain variable node returns to the variable node by using a short route via the check node. When a large number of small cycles are generated in this way, the decoding performance may not be improved to a prescribed level or a higher level in some cases.

In the following embodiments, learning data is generated and learned so that the decoding performance of the Weighted-BP can be further improved.

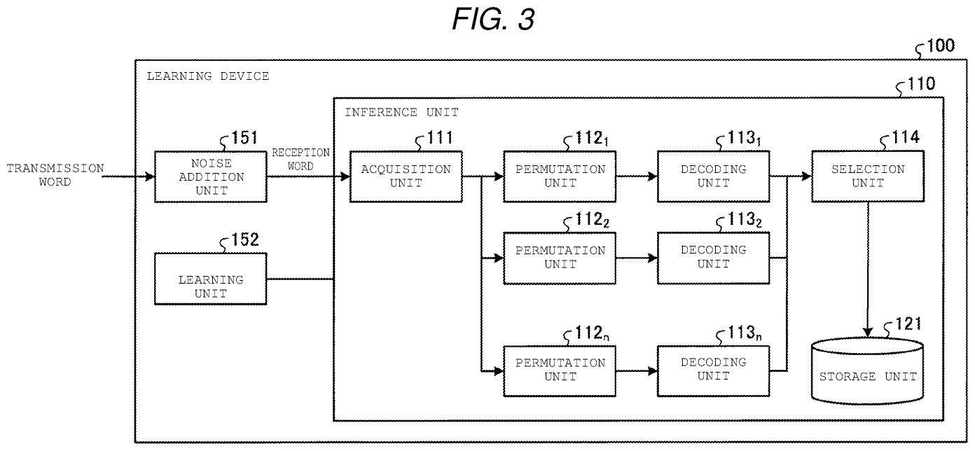

FIG. 3 is a block diagram illustrating an example of a configuration of a learning device 100 according to an embodiment. As illustrated in FIG. 3, the learning device 100 of the present embodiment includes an inference unit 110, a noise addition unit 151, and a learning unit 152. The inference unit 110 includes an acquisition unit 111, permutation units 112₁ to 112ₙ decoding units 113₁ to 113ₙ a selection unit 114, and a storage unit 121. The permutation units 112₁ to 112ₙ each correspond to the decoding units 113₁ to 113ₙ. The noise addition unit 151 may be referred to as an encoding unit.

Here, n is an integer of 2 or more representing the number of the permutation units 112₁ to 112ₙ and the decoding units 113₁ to 113ₙ. When it is not necessary to distinguish the permutation units 112₁ to 112ₙ from each other, all of these may be simply referred to as a permutation unit 112 in some cases. Similarly, when it is not necessary to distinguish the decoding units 113₁ to 113ₙ from each other, all of these may be simply referred to as a decoding unit 113 in some cases.

The inference unit 110 performs inference (decoding) by using the Weighted-BP method. During the inference, for example, the inference unit 110 reads the weight from the storage unit 121, performs an inference based on the Weighted-BP by using the weight that has been, and then stores a code word (decoding result) serving as an inference result in the storage unit 121, for example. The inference unit 110 is used to generate information on forward propagation for learning the weight factors of the Weighted-BP when weight is learned by the learning unit 152. During the learning, the inference unit 110 causes the storage unit 121 to store learning information (used for the learning of the learning unit 152) in addition to the decoding result.

The noise addition unit 151 outputs a code word (reception word) in which noise is added to the input code word (transmission word). For example, the noise addition unit 151 outputs the LLR corresponding to the code word in which the noise is added to the acquired code word, as a code word having the added noise, which may be referred to as an encoded word. For example, the noise addition unit 151 calculates the LLR on an assumption that likelihood in which the sign bit is 0 and likelihood in which the sign bit is 1 respectively follow a normal distribution, and outputs the LLR as the code word having the added noise.

A method of inputting or providing data, such as the transmission word, to the learning device 100 may be any desired method. For example, a method for acquiring data from an external device (such as a server device) via a network and a method of acquiring data by reading data stored in a storage medium may be applicable. The network may have any desired form. For example, the Internet and a LAN (local area network) may be adopted. The network may be wired or wireless.

The acquisition unit 111 acquires various data used in various processes performed by the learning device 100. For example, the acquisition unit 111 acquires the reception word output from the noise addition unit 151 during the learning.

The permutation units 112₁ to 112ₙ respectively output the reception words (second reception words) for which the acquired reception words (first reception words) are permutated by using mutually different permutation methods. For example, each permutation method is automorphism permutation (permutation). As an encoding method, an encoding method having a property that the reception word permutated by using the automorphism permutation can be decoded by using the same decoding method is used. As this encoding method, there are an encoding method using a BCH code and an encoding method using an RS code.

In this encoding method, even if decoding fails when the reception word is not permutated, there are some cases in which the decoding succeed when the reception word is permutated. Therefore, in the present embodiment, the reception words are permutated by using a plurality of permutation methods, and the reception words permutated by using the plurality of corresponding decoding units 113 are respectively decoded. The selection unit 114 selects an optimum decoding result from a plurality of decoding results. In this manner, it is possible to improve the decoding performance.

An example of automorphism permutation will be described. In the following description, an example will be described in which a primitive BCH code is used as the encoding method. However, the same procedure is applicable to other encoding methods having automorphism.

Equation (4) below is an example of a definition of an automorphism group for the primitive BCH code having a code length of (2ⁿ-1) bits. However, GF (2^{m}) represents a finite field having an order of 2ⁿ. In addition, GF (2^{m}) \ {0} means a set obtained by removing zero from GF (2^{m}).

G_{1,m}={az²ⁱ|a∈GF(2^{m})\{0},0≤i<} (4)

The automorphism group defined by Equation (4) can be used for any desired natural number m≥3. Depending on conditions, in some cases, the automorphism group may exist in addition to the set defined by Equation (4).

Equation (4) is the equation of the automorphism group that can be more generally used. Accordingly, Equation (4) will be described below as an example.

The parity-check matrix of the primitive BCH code having the code length of (2^{m}-1) bits has a form in which (2^{m}-1) elements 1 (=α⁰, α¹, α², . . . , a\hat{ }(2ⁿ-2) in GF (2^{m}) \ {0} are aligned. For example, in a case of the BCH code having the code length of 7 bits (m=3), an example of the parity-check matrix is expressed as Equation (5) below.

Hₘ₌₃=[α⁰,α¹,α²,α³,α⁴,α⁵,α⁶] (5)

The code word corresponding to the parity-check matrix Hₙ₌₃ in Equation (5) is represented by [b₀, b₁, b₂, b₃, b₄, b₅, b₆], bk∈{0,1}. In order to determine one automorphism permutation, one combination of a and i in Equation (4) is first determined. For example, a=α² and i=0 are set. At this time, a first half term inside a right side of Equation (4) satisfies az\hat{ }2¹=α²z. When respective terms of the parity-check matrix Hₙ₋₃ are substituted and aligned for the z, the result is expressed as Equation (6) below. The first row is transformed into the second row on the right side because of αk=α\hat{ }(k mod (2ⁿ-1)).

$${H}_{m = 3} ( a = {a}^{2} , i = 0 ) = [ {α}^{2} , {α}^{3} , {α}^{4} , {α}^{5} , {α}^{6} , {α}^{7} , {α}^{8} ] = [ {α}^{2} , {α}^{3} , {α}^{4} , {α}^{5} , {α}^{6} , {α}^{0} , {α}^{1} ] \qquad ( 6 )$$

The permutation of the code word corresponding to Equation (6) is the permutation for which the original code word has been cyclically shifted to the right by 2 bits as in [b₂, b₃, b₀, b₁].

Since the combination of a and i is changed, a plurality of mutually different automorphism permutations can be determined. The permutation units 112₁ to 112ₙ respectively perform the plurality of mutually different automorphism permutations determined in this way.

In the automorphism permutation which can be generated by Equation (4), the number of possible values of i is m, and the number of possible values of a is (2^{m}-1). Accordingly, the number of possible combinations of a and i is m(2^{m}-1). In addition, when i=0 is satisfied, a=α^{k} represents a cyclic shift of k bits to the right. In the primitive BCH code, even how many bits the cyclic shift has, the automorphism permutation is performed.

So far, an example of the automorphism permutation using the cyclic shift has been described. However, the automorphism permutation using a method other than the cyclic shift may be applied.

The decoding units 113₁ to 113ₙ input the permutated reception words output from each of the corresponding permutation units 112₁ to 112ₙ decode the input reception words by using the Weighted-BP, and output the decoding result (decoded word). For example, the weights used by the respective decoding units 113₁ to 113ₙ in the Weighted-BP are stored in the storage unit 121 in association with identification information (for example, numerical values of 1 to n) for identifying the respective decoding units 113.

The selection unit 114 selects one or more decoding results from a plurality (n-number) decoding results output from the decoding units 113₁ to 113ₙ based on a predetermined rule. For example, the selection unit 114 calculates a metric value indicating how good the decoding state (e.g., accuracy of decoding) for the n-number result of the decoding results is considered, and then selects a decoding result for which the metric value is better than that of other decoding results. For example, the decoding result to be selected may be the one decoding result corresponding to a best metric value, may be a predetermined number of decoding results selected in order of the metric value (e.g., from best to worse) is better, or may be one or more decoding results for which the metric value is equal to or better than a threshold. For example, the metric value is the number of value “1” in a syndrome of the decoding result, and a Euclidean distance between the transmission word and the decoding result.

For example, the selection unit 114 causes the storage unit 121 to store the selected decoding result and information (the learning information) used for the learning of the learning unit 152. For example, the learning information includes learning data including the reception word and the transmission word before the permutation corresponding to the decoding result, and identification information for identifying the decoding units 113₁ to 113ₙ from which the decoding result is obtained.

The storage unit 121 stores various data used in various processes performed by the learning device 100. For example, the storage unit 121 stores data such as the reception word acquired by the acquisition unit 111, the learning information, and a parameter (weight) of the neural network used for the Weighted-BP. The storage unit 121 may include any commonly used storage medium such as a flash memory, a memory card, a random access memory (RAM), a hard disk drive (HDD), and an optical disk.

A plurality of the storage units 121 may be provided according to data to be stored. For example, a storage unit that stores learned the parameter (weights) and a storage unit that stores the decoding result may be provided.

The learning unit 152 learns the weight of the weighted-BP by using the learning data including the reception word corresponding to the decoding result selected by the selection unit 114. For example, the learning unit 152 learns the weight of the neural network as described above by using a back propagation method (gradient descent method).

For example, the learning unit 152 uses the learning data included in the learning information stored in the storage unit 121, and learns the weight of the Weighted-BP used by the decoding unit 113 identified by the identification information included in the learning information. The learning unit 152 stores the learned weight in the storage unit 121.

The reception word included in the learning data is used as a decoding target of the Weighted-BP, that is, an input to the neural network used for the Weighted-BP. The transmission word included in the learning data is used as correct answer data. That is, the learning unit 152 learns the weight so that the decoding result of the Weighted-BP for the input reception word is closer to the transmission word which is the correct answer data.

Each of the above-described units (the inference unit 110, the noise addition unit 151, and the learning unit 152) is implemented by one or a plurality of processors, for example. For example, each of the above-described units may be implemented by causing a processor such as a central processing unit (CPU) to execute a program, that is, by using software. Each of the above-described units may be implemented by a processor such as a dedicated integrated circuit (IC), that is, by using hardware. Each of the above-described units may be implemented in a combination of the software and the hardware. When the plurality of processors are used, each processor may implement one of the respective units, or may implement two or more units out of the respective units.

Elements (for example, the noise addition unit 151 and the learning unit 152) used in the learning process may be attachable to and detachable from the inference unit 110. According to this configuration, for example, the following usage may be adopted. The elements required for the learning are attached and used only during the learning, and the elements are detached during the inference using the weight obtained by the learning.

For example, the elements used in the learning process may be implemented by a circuit different from a circuit that implements the inference unit 110, and may be connected to the circuit that implements the inference unit 110 only during the learning. A device (learning device) including elements used for the learning process and a device (inference device or decoding device) including an inference unit 110 may be configured to be separate from each other. In this manner, for example, a configuration may be adopted so that the learning device and the inference device are used by being connected to each other via a network only during the learning. The inference device (decoding device) may be a memory system having a function of decoding data read from a storage device such as a NAND flash memory, as the reception word.

During the learning, the weight of the neural network expressing the message propagation on the Tanner graph is learned. However, the Weighted-BP using the Tanner graph may be performed during the inference using the weight after the learning.

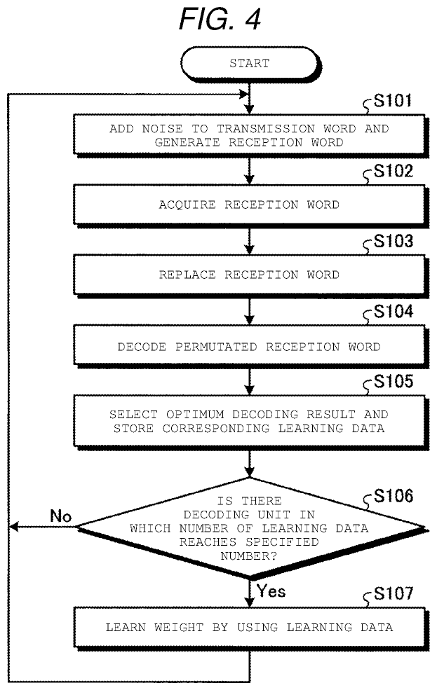

Next, a learning process performed by the learning device 100 according to the present embodiment configured in this way will be described. FIG. 4 is a flowchart illustrating an example of the learning process in an embodiment.

The noise addition unit 151 outputs the reception word to which noise has been added to the input transmission word (Step S101). The acquisition unit 111 acquires the reception word output from the noise addition unit 151 (Step S102). The plurality of permutation units 112₁ to 112ₙ respectively replace the reception word, and output the permutated reception words (Step S103). The plurality of decoding units 113₁ to 113ₙ respectively decode the reception words permutated by the corresponding permutation unit 112, and output the decoding result (Step S104).

The selection unit 114 selects the optimum decoding result from the plurality of decoding results output from the plurality of decoding units 113₁ to 113ₙ and stores the optimum decoding result in the storage unit 121 (Step S105). During the learning process, the selection unit 114 causes the storage unit 121 to store the learning data (the reception word and the transmission word) corresponding to the selected decoding result, and the learning information including the identification information of the corresponding decoding unit 113.

The learning unit 152 determines whether or not there is a decoding unit 113 for which the number of the learning data reaches some specified number set in advance (Step S106). For example, the learning unit 152 obtains the number of the learning data for each identification information included in the learning information, and determines whether or not there is a decoding unit 113 for which the obtained number is equal to or greater than the specified number. For example, the specified number is set as a number corresponding to a batch size of the learning data.

When there is no decoding unit 113 for which the number of the learning data has reached the specified number (Step S106: No), the process returns to Step S101, and the process is repeated. When there is a decoding unit 113 for which the number of the learning data reaches the specified number (Step S106: Yes), the learning unit 152 learns the weight used for the Weighted-BP by the decoding unit 113 for which the number of the learning data has reached the specified number by using the corresponding learning data (Step S107).

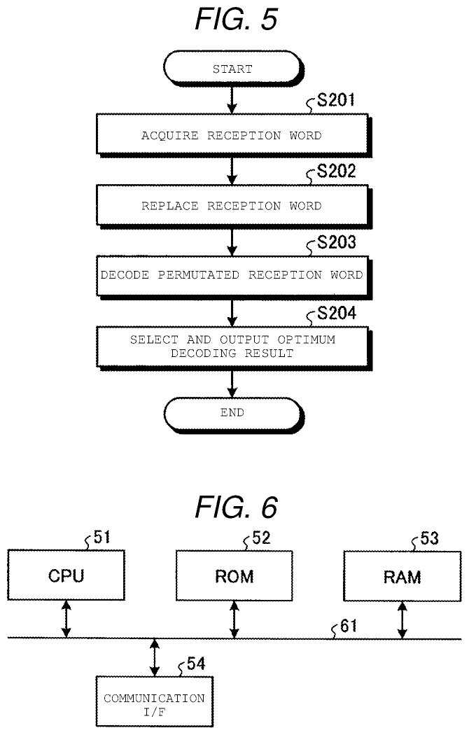

Next, an inference process performed by the learning device 100 according to the present embodiment will be described. The inference process is a process (decoding process or error correction process) in which the reception word is decoded by using the Weighted-BP using the weights learned by performing the learning process so that the decoding result can be output. In some examples, the inference process may be performed by a device (inference device or decoding device) or a circuit separate from the learning device as described above. FIG. 5 is a flowchart illustrating an example of the inference process in an embodiment.

The acquisition unit 111 acquires the reception word serving as the decoding target (Step S201). The process in Step S201 may be the same as the process in Step S102 in FIG. 4. For example, when the data read from the storage device of the memory system is the decoding target, the acquisition unit 111 may acquire the reception word which is the data read from the storage device.

Steps S202 and S203 are the same as Steps S103 and S104 in FIG. 4, and thus, description thereof will be omitted.

The selection unit 114 selects and outputs the optimum decoding result from the plurality of decoding results output from the plurality of decoding units 113₁ to 113ₙ (Step S204).

### MODIFICATION EXAMPLE 1

In the above-described embodiment, a configuration has been described in which only the decoding units 113 for which learning data has been obtained and stored according to identification information identifying the particular decoding units 113 have learned weights. The learning data obtained for one decoding unit 113 (first decoding unit) having the obtained learning data, may be used for the learning of another decoding unit 113 (second decoding unit).

### MODIFICATION EXAMPLE 2

Some of the plurality of decoding units 113 may be configured to use a common weight. In this case, for example, the storage unit 121 may store the weight used in common in association with the identification information of the plurality of decoding units 113 using the common weight. In this manner, storage capacity required for storing the weights can be reduced.

As described above, in the present embodiment, the plurality of decoding units are configured to perform decoding by using the Weighted-BP in parallel. Accordingly, each of the weights of the Weighted-BP can be independently learned. That is, in the present embodiment, not only the plurality of decoding units can be simply disposed in parallel, but also each weight used by each decoding unit can be optimized. Therefore, decoding performance can be further improved.

Next, a hardware configuration of the learning device according to the present embodiment will be described with reference to FIG. 6. FIG. 6 illustrates a hardware configuration example of the learning device according to an embodiment.

The learning device according to the present embodiment includes a control device such as a central processing unit (CPU) 51, a storage device such as a read only memory (ROM) 52 and a random access memory (RAM) 53, a communication I/F 54 connected to a network for communication, and a bus 61 for connecting the respective units to each other.

The program executed by the learning device according to the present embodiment is provided by being pre-installed in the ROM 52.

The program executed by the learning devices according to the present embodiment may be provided as a computer program product in which files in an installable format or an executable format are recorded on a computer-readable recording medium such as a compact disk read only memory (CD-ROM), a flexible disk (FD), a compact disk recordable (CD-R), and a digital versatile disk (DVD).

Furthermore, the program executed by the learning devices according to the present embodiment may be provided as follows. The program may be stored in a computer connected to a network such as the Internet, and may be downloaded via the network. The program executed by the learning devices according to the present embodiment may be provided or distributed via the network such as the Internet.

The program executed by the learning device according to the present embodiment may cause a computer to function as each unit of the above-described learning device. In the computer, the CPU 51 can execute the program by reading the program from the computer-readable storage medium onto the main storage device.

For example, the learning device according to the present embodiment may be implemented by a server device and a personal computer which have the hardware configuration illustrated in FIG. 6. The hardware configuration of the learning device is not limited thereto, and may be implemented by a server device in a cloud environment, for example.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A learning device, comprising:
an encoding unit configured to generate an encoded word by encoding a transmission word;
a plurality of permutation units configured to permutate the encoded word according to different permutation manners to generate a plurality of permutated encoded words;
a plurality of decoding units configured to perform message passing decoding on the plurality of permutated encoded words, respectively, to generate a plurality of decoded words, the message passing decoding involving weighting of values of a word transmitted during the message passing decoding;
a selection unit configured to select one or more of the decoded words; and
a learning unit configured to perform learning of weighting values of the weighting based on the transmission word and the selected one or more of the decoded words.

2. The learning device according to claim 1, wherein the encoding unit generates the encoded word by adding noise to the transmission word to generate a noise-added transmission word and calculating a log-likelihood ratio (LLR) of the noise-added transmission word.

3. The learning device according to claim 1, wherein the selection unit is configured to select one of the decoded words of which syndrome includes a least number of value of “1”.

4. The learning device according to claim 1, wherein the selection unit is configured to select one of the decoded words that has values of the closest Euclidian distance from values of the transmission word.

5. The learning device according to claim 1, wherein the selection unit is configured to:
calculate a metric value representing an accuracy of the message passing decoding, with respect to each of the decoded words, and
select one or more of the decoded words of which metric value is less than a threshold.

6. The learning device according to claim 1, wherein the selection unit is configured to:
calculate a metric value representing an accuracy of the message passing decoding, with respect to each of the decoded words, and
select a predetermined number decoded words from the plurality of decoded words in the order of the metric value.

7. The learning device according to claim 1, wherein
the plurality of decoding units includes a first decoding unit, and
the learning unit is configured to perform learning of weighting values of the weighting used in the first decoding unit based on the decoded word generated by the first decoding unit.

8. The learning device according to claim 1, wherein
the plurality of decoding units includes a first decoding unit and a second decoding unit, and
the learning unit is configured to perform learning of weighting values of the weighting used in the second decoding unit based on the decoded word generated by the first decoding unit.

9. The learning device according to claim 1, wherein at least one of weighting values of the weighting is used by two or more of the decoding units.

10. The learning device according to claim 1, wherein the message passing decoding involves belief propagation of a word of which values are weighted.

11. A learning method, comprising:
encoding a transmission word into an encoded word;
permutating the encoded word according to different permutation manners to generate a plurality of permutated encoded words;
performing message passing decoding on the plurality of permutated encoded words to generate a plurality of decoded words, the message passing decoding involving weighting of values of a word transmitted during the message passing decoding;
selecting one or more of the decoded words; and
performing learning of weighting values of the weighting based on the transmission word and the selected one or more of the decoded words.

12. The learning method according to claim 11, wherein the encoded word is generated by adding noise to the transmission word to generate a noise-added transmission word and calculating a log-likelihood ratio (LLR) of the noise-added transmission word.

13. The learning method according to claim 11, wherein said selecting comprises selecting one of the decoded words of which syndrome includes a least number of value of “1”.

14. The learning method according to claim 11, wherein said selecting comprises selecting one of the decoded words that has values of the closest Euclidian distance from values of the transmission word.

15. The learning method according to claim 11, wherein said selecting comprises:
calculating a metric value representing an accuracy of the message passing decoding, with respect to each of the decoded words, and
selecting one or more of the decoded words of which metric value is less than a threshold.

16. The learning method according to claim 11, wherein said selecting comprises:
calculating a metric value representing an accuracy of the message passing decoding, with respect to each of the decoded words; and
selecting a predetermined number decoded words from the plurality of decoded words in the order of the metric value.

17. The learning method according to claim 11, wherein
the permutated encoded words are generated by a plurality of decoding units, respectively, the plurality of decoding units including a first decoding unit, and
said performing the learning comprises performing learning of weighting values of the weighting used in the first decoding unit based on the decoded word generated by the first decoding unit.

18. The learning method according to claim 11, wherein
the permutated encoded words are generated by a plurality of decoding units, respectively, the plurality of decoding units including a first decoding unit and a second decoding unit, and
said performing the learning comprises performing learning of weighting values of the weighting used in the second decoding unit based on the decoded word generated by the first decoding unit.

19. The learning method according to claim 11, wherein
the permutated encoded words are generated by a plurality of decoding units, respectively, the plurality of decoding units, and
at least one of weighting values of the weighting are commonly used in the decoding units.

20. The learning method according to claim 11, wherein the message passing decoding involves belief propagation of a word of which values are weighted.
